(19) United States
(12) Patent Application Publication
(10) Pub. No.: US 2021/0013694 A1
(43) Pub. Date: Jan. 14, 2021

(54) OPTICAL MODULE

(71) Applicant: Mitsubishi Electric Corporation, Tokyo (JP)

(72) Inventors: Kei MASUYAMA, Tokyo (JP); Kiyotomo HASEGAWA, Tokyo (JP); Keita MOCHIZUKI, Tokyo (JP)

(73) Assignee: Mitsubishi Electric Corporation, Tokyo (JP)

(21) Appl. No.: 17/032,858

(22) Filed: Sep. 25, 2020

Related U.S. Application Data
(63) Continuation of application No. PCT/JP2018/015258, filed on Apr. 11, 2018.

(51) Int. Cl. H01S 5/024; H04B 10/40; H01S 5/022

(52) U.S. Cl. CPC H01S 5/024; H01S 5/02284; H04B 10/40

(57) ABSTRACT

An optical module includes a package including a first member made of a metal material and a second member made of a non-conductive material, the second member facing the first member; a temperature controller fixed in such a manner that one end surface of the temperature controller comes into contact with a surface in a direction of the second member in the first member; a carrier made of a non-conductive material and fixed in such a manner that one end surface of the carrier comes into contact with a surface in an opposite direction to the first member in the temperature controller; and a semiconductor element disposed in either one of a direction of the first member and the opposite direction to the first member with respect to the carrier, and fixed in such a manner that one end surface of the semiconductor element comes into contact with a surface in a direction of the first member in the carrier or a surface in the opposite direction to the first member in the carrier, or in such a manner that one end surface of the semiconductor element comes into contact with a surface in the opposite direction to the carrier in a submount made of a non-conductive material and fixed in such a manner that the submount comes in contact with a surface in a direction of the first member in the carrier or a surface in the opposite direction to the first member in the carrier.

### CROSS REFERENCE TO RELATED APPLICATIONS

This application is a Continuation of PCT International Application No. PCT/JP2018/015258, filed on Apr. 11, 2018, which is hereby expressly incorporated by reference into the present application.

### TECHNICAL FIELD

The invention relates to an optical module.

### BACKGROUND ART

Development of miniaturized transceivers is proceeding to achieve large-capacity optical communication networks. A transceiver includes a semiconductor element such as a semiconductor laser or an optical modulator, and the semiconductor element converts an electrical signal into an optical signal and outputs the optical signal, and sends out the optical signal. The semiconductor element generates heat when converting an electrical signal into an optical signal. However, since the wavelength of the optical signal to be emitted from the semiconductor element changes depending on the temperature of the semiconductor element, a temperature controller for adjusting the temperature of the semiconductor element needs to abut on the semiconductor element.

To achieve miniaturization of a transceiver, Non-Patent Literature 1 discloses a transceiver that uses a surface-mount package in which circuits for controlling the semiconductor element are mounted at high density. The transceiver of Non-Patent Literature 1 includes a package including circuits for controlling conductor elements, a semiconductor element, and a temperature controller. The package of Non-Patent Literature 1 is structured in such a manner that an interposer of the package is connected to an electrical signal wiring board through contact pins, and heat generated inside the package is dissipated outside the package through the contact pins.

### CITATION LIST

### Non-Patent Literatures

Non-Patent Literature 1: Optical Internetworking Forum, Contribution Number: oif2017.037.00, Working Group: PLL, Title: IC-TROSA BGA mounting options, Source: Evan Baumer, Samtec USA, Date: Jan. 17, 2017

### SUMMARY OF INVENTION

### Technical Problem

Although the transceiver described in Non-Patent Literature 1 is configured in such a manner that the above-described circuits are contained in the package and the semiconductor element and the temperature controller are mounted outside the package, by also containing the semiconductor element and the temperature controller in the package, the transceiver can be further miniaturized.

When the semiconductor element is to be contained in the package, the temperature controller for controlling the temperature of the semiconductor element is disposed so as to be sandwiched between a package member located in a portion in which the contact pins are arranged and the semiconductor element in order to dissipate heat generated from the semiconductor element outside the package.

However, when the temperature controller is disposed so as to be sandwiched between the package member located in a portion in which the contact pins are arranged and the semiconductor element, there is a problem that the power consumption of the temperature controller increases.

The invention is to solve the above-described problem, and an object of the invention is to provide an optical module that suppresses the power consumption of a temperature controller for adjusting the temperature of a semiconductor element to a small level while achieving high-density mounting by containing the semiconductor element in a package.

### Solution to Problem

An optical module according to the invention includes a package including a first member made of a metal material and a second member made of a non-conductive material, the second member facing the first member; a temperature controller fixed in such a manner that one end surface of the temperature controller comes into contact with a surface in a direction of the second member in the first member; a carrier made of a non-conductive material and fixed in such a manner that one end surface of the carrier comes into contact with a surface in an opposite direction to the first member in the temperature controller; and a semiconductor element disposed in either one of a direction of the first member and the opposite direction to the first member with respect to the carrier, and fixed in such a manner that one end surface of the semiconductor element comes into contact with a surface in a direction of the first member in the carrier or a surface in the opposite direction to the first member in the carrier, or in such a manner that one end surface of the semiconductor element comes into contact with a surface in the opposite direction to the carrier in a submount made of a non-conductive material and fixed in such a manner that the submount comes in contact with a surface in a direction of the first member in the carrier or a surface in the opposite direction to the first member in the carrier, and a surface in an opposite direction to the second member in the first member operates as a heat-dissipating surface, and an electrical signal is inputted from a surface in the opposite direction to the first member in the second member, wherein the second member has a recessed portion extending in the direction of the first member, the second member includes a first electrical wiring line passing through the second member from a surface in the opposite direction to the first member in the second member to a surface in the direction of the first member in a part of the recessed portion of the second member, the part extending in the direction of the first member, the carrier includes a second electrical wiring line passing through the carrier from a surface in the direction of the first member in the carrier to a surface in the opposite direction to the first member in the carrier, the carrier is fixed so as to bridge the recessed portion of the second member, the semiconductor element is disposed in the opposite direction to the first member with respect to the carrier, an end portion in the direction of the first member in the first electrical wiring line and an end portion in the direction of the first member in the second electrical wiring line are electrically connected to each other, and an end portion in the opposite direction to the first member in the second electrical wiring line and the semiconductor element are electrically connected to each other.

### Advantageous Effects of Invention

According to the invention, the optical module can be provided and it suppresses the power consumption of the temperature controller for adjusting the temperature of the semiconductor element to a small level while achieving high-density mounting by containing the semiconductor element in the package.

### BRIEF DESCRIPTION OF DRAWINGS

FIG. 1 is a diagram showing a configuration of a transceiver in which an optical module according to a first embodiment is surface-mounted on an electrical signal wiring board.

FIG. 2 is a diagram showing a configuration of a transceiver in which an optical module according to a variant of the first embodiment is surface-mounted on an electrical signal wiring board.

FIG. 3 is a diagram showing a configuration of a transceiver in which an optical module according to a second embodiment is surface-mounted on an electrical signal wiring board.

FIG. 4 is a diagram showing a relationship between the environmental temperature of the transceiver having the optical module according to the second embodiment applied thereto and the power consumption of a temperature controller in the optical module.

FIG. 5 is a diagram showing a configuration of a transceiver in which an optical module according to a variant of the second embodiment is surface-mounted on an electrical signal wiring board.

FIG. 6 is a diagram showing a configuration of a transceiver in which an optical module according to a third embodiment is surface-mounted on an electrical signal wiring board.

FIG. 7 is a diagram showing a configuration of a transceiver in which an optical module according to a variant of the third embodiment is surface-mounted on an electrical signal wiring board.

FIG. 8 is a diagram showing a configuration of a transceiver in which an optical module according to a fourth embodiment is surface-mounted on an electrical signal wiring board.

FIG. 9 is a diagram showing a configuration of a transceiver in which an optical module according to a fifth embodiment is surface-mounted on an electrical signal wiring board.

FIG. 10 is a diagram showing a configuration of a transceiver in which a temperature controller is applied to an optical module inferred from Non-Patent Literature 1 and the optical module is surface-mounted on an electrical signal wiring board.

FIG. 11 is a diagram showing a relationship between the environmental temperature of the transceiver having the optical module inferred from Non-Patent Literature 1 applied thereto and the power consumption of the temperature controller in the optical module.

### DESCRIPTION OF EMBODIMENTS

Embodiments of the invention will be described in detail below referring to the drawings.

### First Embodiment

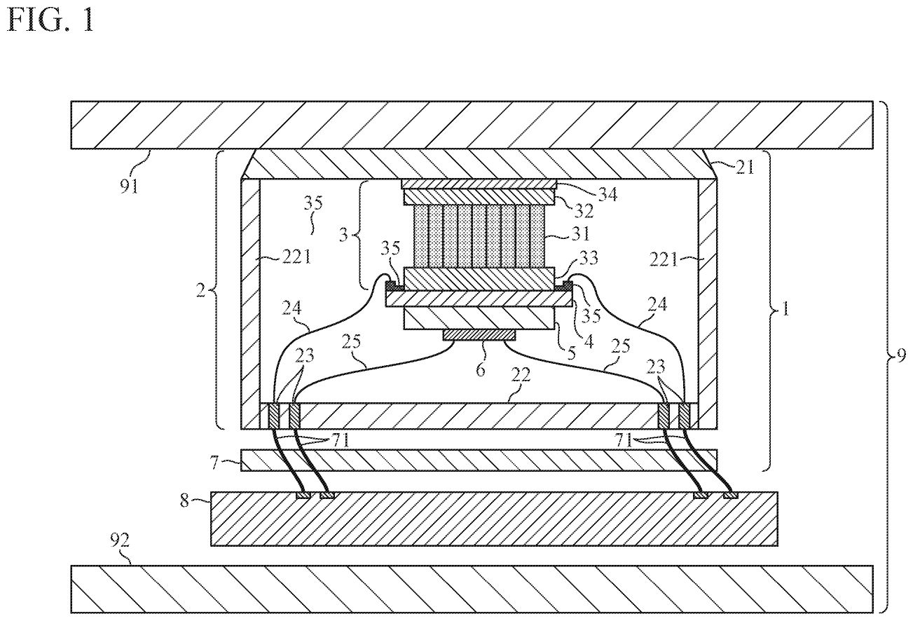

FIG. 1 is a diagram showing a configuration of a transceiver 9 in which an optical module 1 according to a first embodiment is surface-mounted on an electrical signal wiring board 8.

The configuration of the transceiver 9 in which the optical module 1 according to the first embodiment is surface-mounted on the electrical signal wiring board 8 will be described using FIG. 1.

The transceiver 9 according to the first embodiment includes the optical module 1 and the electrical signal wiring board 8.

The electrical signal wiring board 8 is a board for supplying electrical signals and power for driving the optical module 1 to the optical module 1.

The optical module 1 includes a package 2, a semiconductor element 6, a submount 5, a carrier 4, a temperature controller 3, and an interposer 7.

The package 2 is an exterior member that contains therein the semiconductor element 6, the submount 5, the carrier 4, and the temperature controller 3. The semiconductor element 6, the submount 5, the carrier 4, and the temperature controller 3 will be described later. The package 2 is made of a combination of a metal material and a non-conductive material. The package 2 includes a member made of a metal material (hereinafter, referred to as “first member 21”) and a member facing the first member 21 (hereinafter, referred to as “second member 22”). The second member 22 is made of, for example, a non-conductive material with high thermal conductivity which is represented by ceramic materials such as aluminum nitride and aluminum oxide. The package 2 includes members substantially perpendicular to the first member 21 and the second member 22 (hereinafter, referred to as “perpendicular members 221”), in addition to the first member 21 and the second member 22.

The semiconductor element 6 is a semiconductor member such as a semiconductor laser or an optical modulator that converts an inputted electrical signal into an optical signal and outputs the optical signal.

The submount 5 is a member for mounting the semiconductor element 6 thereon. The submount 5 is made of, for example, a non-conductive material with high thermal conductivity which is represented by ceramic materials such as aluminum nitride and aluminum oxide.

The carrier 4 is a board for mounting the temperature controller 3 thereon. The carrier 4 is made of, for example, a non-conductive material with high thermal conductivity which is represented by ceramic materials such as aluminum nitride and aluminum oxide.

The temperature controller 3 includes, as an example, a Peltier element 31; and temperature controller's exterior members 32 and 33 made of a non-conductive material with high thermal conductivity which is represented by ceramic materials such as aluminum nitride and aluminum oxide. In the temperature controller 3, the Peltier element 31 is a temperature controllable member, and absorbs heat from the temperature controller's exterior member 33 and dissipates the heat to the temperature controller's exterior member 32.

The interposer 7 is a member present between the second member 22 and the electrical signal wiring board 8, and is a relay member such as a board for facilitating mounting of the optical module 1 on the electrical signal wiring board 8. The electrical signal wiring board 8 and end portions in an opposite direction to the first member 21 in electrical wiring lines which will be described later (hereinafter, referred to as “first electrical wiring lines 23”) are electrically connected to each other through the interposer 7.

The optical module 1 converts an electrical signal inputted from the electrical signal wiring board 8 into an optical signal by the semiconductor element 6, and sends out the optical signal to a source external to the optical module 1.

An arrangement of the semiconductor element 6, the temperature controller 3, the carrier 4, and the submount 5 in the package 2 will be described.

The temperature controller 3 is fixed in such a manner that one end surface thereof made of a non-conductive material comes into contact with a surface in a direction of the second member 22 in the first member 21. Namely, the temperature controller 3 is fixed in such a manner that a surface in an opposite direction to the Peltier element 31 in the temperature controller's exterior member 32 comes into contact with the surface in the direction of the second member 22 in the first member 21. The temperature controller 3 may include a heat-dissipating member 34 such as heat-dissipating gel or a heat-dissipating sheet on the surface in the opposite direction to the Peltier element 31 in the temperature controller's exterior member 32. In this case, the optical module 1 is configured in such a manner that the heat-dissipating member 34 is sandwiched between the temperature controller's exterior member 32 and the first member 21, and the temperature controller 3 is fixed so as to come into contact with the first member 21.

The carrier 4 is fixed in such a manner that one end surface thereof comes into contact with a surface in the opposite direction to the first member 21 in the temperature controller 3. Namely, the carrier 4 is fixed in such a manner that a surface in a direction of the first member 21 in the carrier 4 comes into contact with a surface in the opposite direction to the Peltier element 31 in the temperature controller's exterior member 33.

The submount 5 is fixed in such a manner that one end surface thereof comes into contact with a surface in the opposite direction to the first member 21 in the carrier 4.

The semiconductor element 6 is fixed in such a manner that one end surface thereof comes into contact with a surface in the opposite direction to the first member 21 in the submount 5.

Namely, the submount 5 and the semiconductor element 6 are arranged in the opposite direction to the first member 21 with respect to the carrier 4.

Electrical connections of the optical module 1 will be described.

The second member 22 includes the first electrical wiring lines 23 that pass therethrough from a surface in the opposite direction to the first member 21 in the second member 22 to a surface in the direction of the first member 21 in the second member 22.

End portions in the opposite direction to the first member 21 in the first electrical wiring lines 23 and the electrical signal wiring board 8 are electrically connected to each other by electrical wiring lines 71 through the interposer 7. By this configuration, the optical module 1 is surface-mounted on the electrical signal wiring board 8.

End portions in the direction of the first member 21 in the first electrical wiring lines 23 and the semiconductor element 6 are electrically connected to each other by electrical wiring lines 25 such as conductive wires.

End portions in the direction of the first member 21 in the first electrical wiring lines 23 and the temperature controller 3 are electrically connected to each other by electrical wiring lines 24 such as conductive wires through pole electrodes 35 provided on the temperature controller 3.

Operation of the optical module 1 will be described.

The optical module 1 operates on the basis of electrical signals inputted from the electrical signal wiring board 8 which are electrically connected thereto as described above.

The semiconductor element 6 converts electrical signals inputted from the electrical signal wiring board 8 through the electrical wiring lines 71, the first electrical wiring lines 23, and the electrical wiring lines 25 into optical signals.

The semiconductor element 6 generates heat when driven.

The temperature controller 3 operates by power supplied from the electrical signal wiring board 8 through the electrical wiring lines 71, the first electrical wiring lines 23, and the electrical wiring lines 24. The temperature controller 3 absorbs heat generated by the semiconductor element 6 through the submount 5 and the carrier 4, and dissipates the heat to the first member 21.

The first member 21 is in contact with an inner surface of a transceiver housing 91 made of a metal material, etc., on a surface in an opposite direction to the second member 22 in the first member 21 that operates as a heat-dissipating surface, and the first member 21 dissipates the heat dissipated from the temperature controller 3 to the transceiver housing 91.

A variant of the first embodiment will be described.

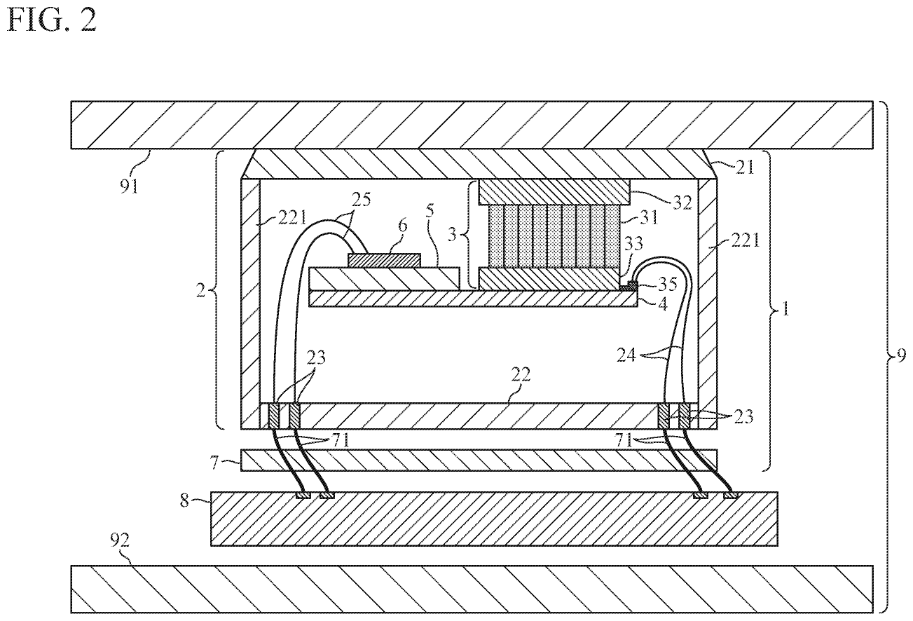

FIG. 2 is a diagram showing a configuration of a transceiver 9 in which an optical module 1 according to the variant of the first embodiment is surface-mounted on an electrical signal wiring board 8.

The configuration of the transceiver 9 in which the optical module 1 according to the variant of the first embodiment is surface-mounted on the electrical signal wiring board 8 will be described using FIG. 2.

In description of the optical module 1 according to the variant of the first embodiment, description of content overlapping the content described in the embodiment so far is omitted.

A difference between the optical module 1 according to the first embodiment and the optical module 1 according to the variant of the first embodiment is as follows.

In the optical module 1 according to the first embodiment, the submount 5 and the semiconductor element 6 are arranged in the opposite direction to the first member 21 with respect to the carrier 4.

On the other hand, in the optical module 1 according to the variant of the first embodiment, a submount 5 and a semiconductor element 6 are arranged in the direction of the first member 21 with respect to a carrier 4.

The optical module 1 according to the variant of the first embodiment is the same as the optical module 1 described using FIG. 1 in the first embodiment, except the above-described arrangement of the submount 5 and the semiconductor element 6, and thus, description thereof is omitted.

Although the embodiment described so far shows an example in which the semiconductor element 6 is fixed to the carrier 4 through the submount 5, the semiconductor element 6 may be fixed so as to come into direct contact with the carrier 4, without through the submount 5.

As described above, the optical module 1 includes the package 2 including the first member 21 made of a metal material, and the second member 22 made of a non-conductive material, the second member 22 facing the first member 21; the temperature controller 3 fixed in such a manner that one end surface thereof comes into contact with a surface in a direction of the second member 22 in the first member 21; the carrier 4 made of a non-conductive material and fixed in such a manner that one end surface thereof comes into contact with a surface in the direction of the second member 22 in the temperature controller 3; and the semiconductor element 6 disposed in either one of the direction of the second member 22 and an opposite direction to the second member 22 with respect to the carrier 4, and fixed in such a manner that one end surface thereof comes into contact with a surface in a direction of the second member 22 in the carrier 4 or a surface in the opposite direction to the second member 22 in the carrier 4, or in such a manner that one end surface thereof comes into contact with a surface in the opposite direction to the carrier 4 in a submount 5 made of a non-conductive material and fixed in such a manner that the submount 5 comes in contact with a surface in a direction of the second member 22 in the carrier 4 or a surface in the opposite direction to the second member 22 in the carrier 4.

By such a configuration, the optical module 1 can be provided that suppresses the power consumption of the temperature controller 3 for adjusting the temperature of the semiconductor element 6 to a small level while achieving high-density mounting by containing the semiconductor element 6 in the package 2.

### Second Embodiment

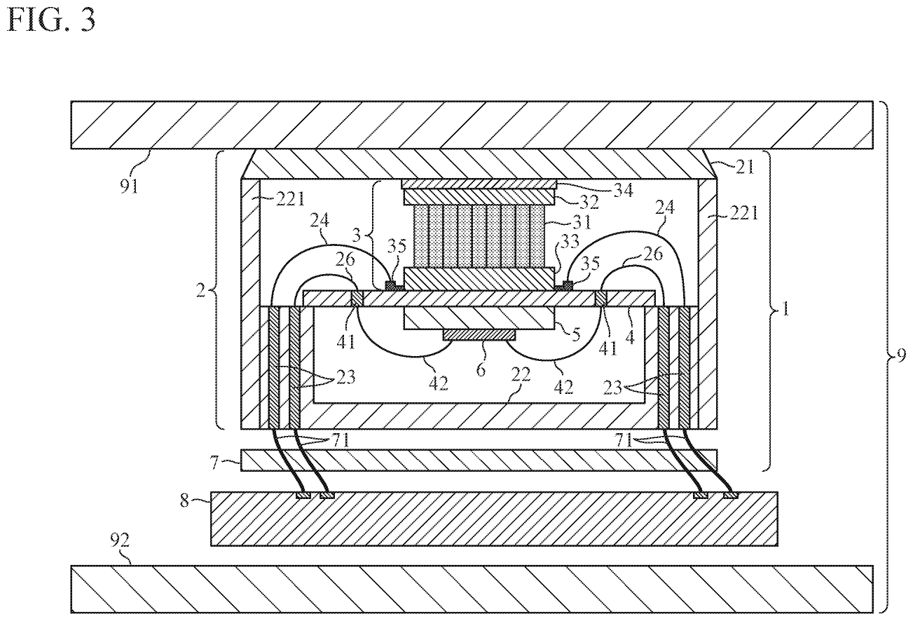

FIG. 3 is a diagram showing a configuration of a transceiver 9 in which an optical module 1 according to a second embodiment is surface-mounted on an electrical signal wiring board 8.

The configuration of the transceiver 9 in which the optical module 1 according to the second embodiment is surface-mounted on the electrical signal wiring board 8 will be described using FIG. 3.

In description of the optical module 1 according to the second embodiment, description of content overlapping the content described in the embodiment so far is omitted.

Differences between the optical module 1 according to the first embodiment and the optical module 1 according to the second embodiment are as follows:

The second member 22 in the optical module 1 according to the first embodiment has a flat shape.

On the other hand, a second member 22 in the optical module 1 according to the second embodiment has a recessed portion extending in a direction of a first member 21. The recessed portion of the second member 22 includes a planar part facing the first member 21 (hereinafter, referred to as “bottom portion”) and parts extending in the direction of the first member 21 (hereinafter, referred to as “side portions”). The side portions of the second member 22 are located in a direction substantially parallel to a direction in which optical signals outputted from a semiconductor element 6 are sent out to a source external to a package 2, and make a pair facing each other with the semiconductor element 6 sandwiched therebetween.

In addition, the carrier 4 in the optical module 1 according to the first embodiment is only fixed so as to come into contact with a surface in the opposite direction to the first member 21 in the temperature controller 3.

On the other hand, a carrier 4 in the optical module 1 according to the second embodiment is fixed in such a manner that each of one end side of the carrier 4 and an other end side facing the one end side bridges the recessed portion of the second member 22 with a corresponding one of the side portions of the second member 22 which make a pair.

By such a configuration, compared to the optical module 1 according to the first embodiment, electrical wiring lines such as conductive wires are shortened, enabling to provide the optical module 1 with improved high-frequency characteristics when the semiconductor element 6 operates at high speed.

Electrical connections of the optical module 1 according to the second embodiment will be described.

First electrical wiring lines 23 in the optical module 1 according to the second embodiment pass through the second member 22 from a surface in an opposite direction to the first member 21 in the second member 22 to surfaces in the direction of the first member 21 in the side portions of the second member 22.

In addition, the carrier 4 in the optical module 1 according to the second embodiment includes electrical wiring lines (hereinafter, referred to as “second electrical wiring lines 41”) that pass therethrough from a surface in the direction of the first member 21 in the carrier 4 to a surface in the opposite direction to the first member 21 in the carrier 4.

An end portion in the direction of the first member 21 in a first electrical wiring line 23 and an end portion in the direction of the first member 21 in a second electrical wiring line 41 are electrically connected to each other by an electrical wiring line 26 such as a conductive wire.

An end portion in the opposite direction to the first member 21 in each second electrical wiring line 41 and the semiconductor element 6 are electrically connected to each other by an electrical wiring line 42 such as a conductive wire.

Operation of the optical module 1 is the same as that of the optical module 1 according to the first embodiment and thus description thereof is omitted.

Exemplary computation of power consumption of a temperature controller 3 in the optical module 1 according to the second embodiment with respect to the environmental temperature of the transceiver 9 having the optical module 1 applied thereto is shown below. The environmental temperature of the transceiver 9 is the outside ambient temperature of the transceiver 9. In addition, the temperature controller 3 uses a Peltier element 31.

The temperature controller 3 includes a temperature controller's exterior member 32 made of aluminum nitride and being in the form of a rectangular parallelepiped with a short side of 10 millimeters, a long side of 20 millimeters, and a thickness of 0.8 millimeters. The thermal conductivity of the temperature controller's exterior member 32 is 170 watts per meter kelvin. When a surface of the Peltier element 31 used in the temperature controller 3 on which the Peltier element 31 and the temperature controller's exterior member 32 come into contact with each other is rectangular with a short side of 5 millimeters and a long side of 7 millimeters, the thermal resistance of the temperature controller's exterior member 32 is 0.135 kelvin per watt. When heat-dissipating gel with a thermal conductivity of 1.5 watts per meter kelvin is applied at a thickness of 0.4 millimeters as a heat-dissipating member 34 between the temperature controller's exterior member 32 and the first member 21, the thermal resistance of the heat-dissipating gel is 1.333 kelvin per watt. It is assumed that the heating value of the semiconductor element 6 at a time when the semiconductor element 6 is driven at 25 degrees Celsius is 0.7 watts.

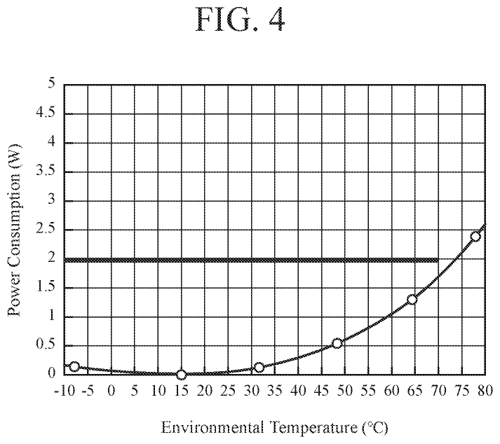

FIG. 4 is a diagram showing a relationship between the environmental temperature of the transceiver 9 having the optical module 1 according to the second embodiment applied thereto and the power consumption of the temperature controller 3 in the optical module 1 in the above-described premises. As shown in FIG. 4, the power consumption of the temperature controller 3 is less than or equal to 2.0 watts when the environmental temperature of the transceiver 9 having the optical module 1 according to the second embodiment applied thereto is in a range from 10 degrees below zero to 70 degrees Celsius.

To compare the optical module 1 according to the second embodiment with a conventional surface-mount optical module, exemplary computation of power consumption of a Peltier element of a temperature controller 30 in an optical module 10 inferred from Non-Patent Literature 1 with respect to the environmental temperature of a transceiver 90 having the optical module 10 applied thereto is shown below.

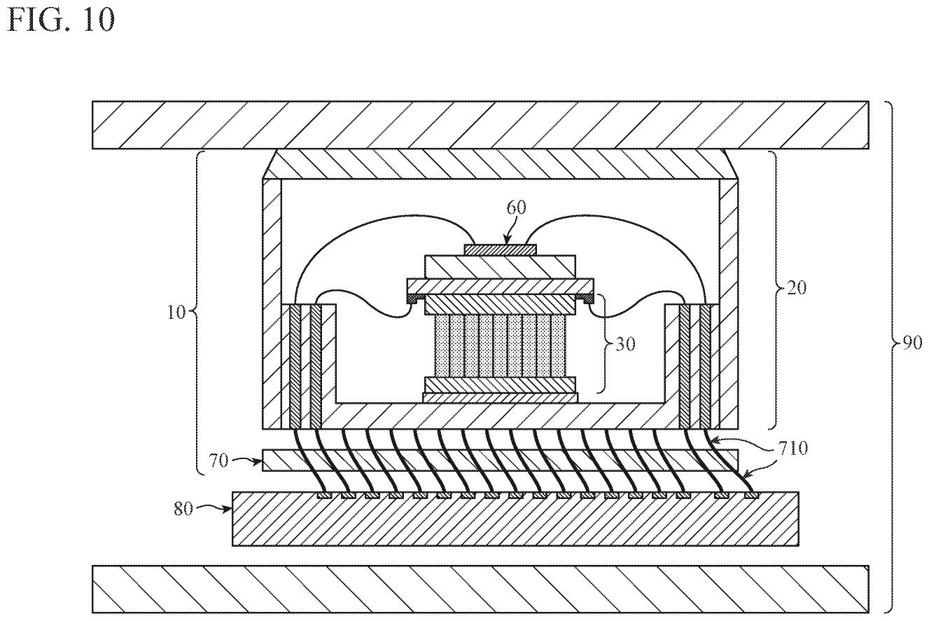

FIG. 10 is a diagram showing a configuration of the transceiver 90 in which the temperature controller 30 is applied to the optical module 10 inferred from Non-Patent Literature 1 and the optical module 10 is surface-mounted on an electrical signal wiring board 80.

For the configuration of the transceiver 90 in which the optical module 10 inferred from Non-Patent Literature 1 is surface-mounted on the electrical signal wiring board 80, only matters that differ from the transceiver 9 in which the optical module 1 according to the second embodiment is surface-mounted on the electrical signal wiring board 8 will be described. Main differences are as follows:

In the optical module 10 inferred from Non-Patent Literature 1, the temperature controller 30 is disposed so as to come into contact with a part made of a non-conductive material instead of a part made of a metal material in a package 20. In the optical module 10 inferred from Non-Patent Literature 1, heat generated inside the optical module 10 is exhausted to the electrical signal wiring board 80 through contact pins 710.

In computation of power consumption of the temperature controller 30 in the optical module 10 inferred from Non-Patent Literature 1 with respect to the environmental temperature of the transceiver 90 having the optical module 10 applied thereto, the thickness and material of the package 20, the size and performance of the temperature controller 30, drive conditions of a semiconductor element 60, etc., are the same as those shown in the exemplary computation of power consumption of the temperature controller 3 in the optical module 1 according to the second embodiment with respect to the environmental temperature of the transceiver 9 having the optical module 1 applied thereto.

It is assumed that the contact pins 710 with a short side of 0.1 millimeters, a long side of 0.4 millimeters, and a length of 0.8 millimeters are arranged with 0.8 millimeter pitches, using beryllium copper with a thermal conductivity of 90 watts per meter kelvin. In this case, the thermal resistance of the contact pins 710 is 9.217 kelvin per watt in total.

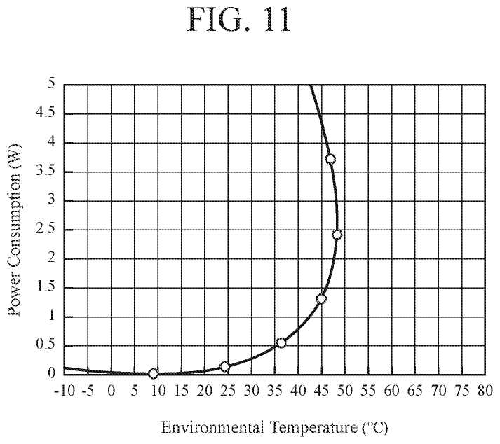

FIG. 11 is a diagram showing a relationship between the environmental temperature of the transceiver 90 having the optical module 10 inferred from Non-Patent Literature 1 applied thereto and the power consumption of the temperature controller 30 in the optical module 10 in the above-described premises.

When the power consumption of the temperature controller 3 in the optical module 1 according to the second embodiment which is shown in FIG. 4 is compared with the power consumption of the temperature controller 30 in the optical module 10 inferred from Non-Patent Literature 1 which is shown in FIG. 11, it can be seen that in a range of environmental temperature from 15 degrees Celsius to 48 degrees Celsius, the power consumption is suppressed to a smaller level with the temperature controller 3 in the optical module 1 according to the second embodiment. Furthermore, as shown in FIG. 11, in the temperature controller 30 in the optical module 10 inferred from Non-Patent Literature 1, power consumption diverges when the environmental temperature is greater than or equal to about 48 degrees Celsius. This fact indicates that the Peltier element has caused thermal runaway and temperature control has not been able to be performed.

A variant of the second embodiment will be described.

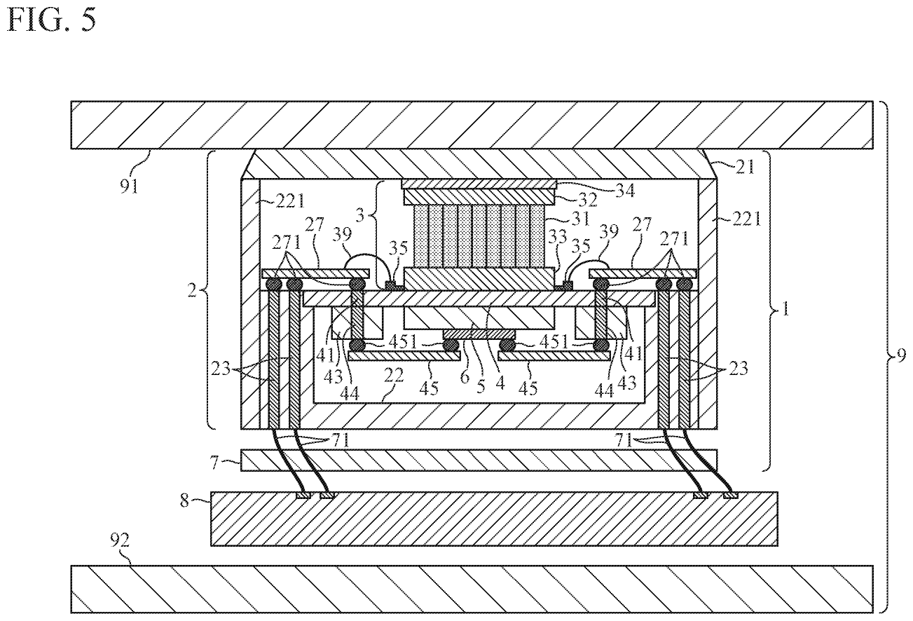

FIG. 5 is a diagram showing a configuration of a transceiver 9 in which an optical module 1 according to the variant of the second embodiment is surface-mounted on an electrical signal wiring board 8.

The configuration of the transceiver 9 in which the optical module 1 according to the variant of the second embodiment is surface-mounted on the electrical signal wiring board 8 will be described using FIG. 5.

In description of the optical module 1 according to the variant of the second embodiment, description of content overlapping the content described in the embodiments so far is omitted.

Differences between the optical module 1 according to the second embodiment and the optical module 1 according to the variant of the second embodiment are as follows.

The optical module 1 according to the variant of the second embodiment includes relay boards (hereinafter, referred to as “first relay boards 43”) which are not included in the optical module 1 according to the second embodiment. Each first relay board 43 is configured in such a manner that one end surface thereof is fixed so as to come into contact with a surface in the opposite direction to a first member 21 in a carrier 4, and a surface in the opposite direction to the first member 21 thereof is located on substantially the same plane as a surface in the opposite direction to the first member 21 in a semiconductor element 6. Each first relay board 43 includes an electrical wiring line (hereinafter, referred to as “third electrical wiring line 44”) that passes therethrough from the surface of the first relay board 43 that comes into contact with the carrier 4 to the surface of the first relay board 43 that faces the surface of the first relay board 43 that comes into contact with the carrier 4.

In the optical module 1 according to the second embodiment, an end portion in the opposite direction to the first member 21 in each second electrical wiring line 41 and the semiconductor element 6 are directly connected to each other by the electrical wiring line 42.

On the other hand, in the optical module 1 according to the variant of the second embodiment, an end portion in an opposite direction to the first member 21 in a second electrical wiring line 41 and an end portion in a direction of the carrier 4 in a third electrical wiring line 44 are in contact with each other and are electrically connected to each other. Furthermore, an end portion in an opposite direction to the carrier 4 in the third electrical wiring line 44 and the semiconductor element 6 are electrically connected to each other, for example, through a relay board (hereinafter, referred to as “second relay board 45”) composed of a board for a flip chip and bumps (hereinafter, referred to as “first bumps 451”).

As such, in the optical module 1 according to the variant of the second embodiment, the end portion in the opposite direction to the first member 21 in the second electrical wiring line 41 and the semiconductor element 6 are electrically connected to each other through the first relay board 43, the second relay board 45, and the first bumps 451.

In the carrier 4 in the optical module 1 according to the second embodiment, a surface of the second member 22 having end portions in the direction of the first member 21 in the first electrical wiring lines 23 and a surface in the direction of the first member 21 in the carrier 4 are not located on substantially the same plane.

On the other hand, in the carrier 4 in the optical module 1 according to the variant of the second embodiment, a surface of a second member 22 having end portions in the direction of the first member 21 in the first electrical wiring lines 23 and a surface in the direction of the first member 21 in the carrier 4 are fixed so as to be located on substantially the same plane.

FIG. 5 shows, as an example, the second member 22 processed in such a manner that a part of each side portion of the second member 22 that is in contact with the carrier 4 in FIG. 3 is cut out by an amount corresponding to the thickness of the carrier 4 in the opposite direction to the first member 21, in order to fix the carrier 4 in such a manner that a surface of the second member 22 having end portions in the direction of the first member 21 in the first electrical wiring lines 23 and a surface in the direction of the first member 21 in the carrier 4 are located on substantially the same plane. Provided that the carrier 4 can be fixed in such a manner that a surface of the second member 22 having end portions in the direction of the first member 21 in the first electrical wiring lines 23 and a surface in the direction of the first member 21 in the carrier 4 are located on substantially the same plane, a structure is not limited to the one shown in FIG. 5, and for example, the carrier 4 may be fixed in such a manner that the side portions of the second member 22 which make a pair sandwich both end sides of the carrier 4.

In the optical module 1 according to the second embodiment, an end portion in the direction of the first member 21 in a first electrical wiring line 23 and an end portion in the direction of the first member 21 in a second electrical wiring line 41 are electrically connected to each other by an electrical wiring line 26. In addition, an end portion in the direction of the first member 21 in a first electrical wiring line 23 and the temperature controller 3 are electrically connected to each other by an electrical wiring line 24 such as a conductive wire through a pole electrode 35 provided on the temperature controller 3.

On the other hand, in the optical module 1 according to the variant of the second embodiment, end portions in the direction of the first member 21 in the first electrical wiring lines 23 and an end portion in the direction of the first member 21 in a second electrical wiring line 41 are electrically connected to each other, for example, through a relay board (hereinafter, referred to as “third relay board 27”) composed of a board for a flip chip and bumps (hereinafter, referred to as “second bumps 271”). In addition, the end portions in the direction of the first member 21 in the first electrical wiring lines 23 and the temperature controller 3 are electrically connected to each other through the second bumps 271, the third relay board 27, an electrical wiring line 39 such as a conductive wire, and a pole electrode 35 provided on the temperature controller 3.

By such a configuration and an arrangement of signal lines near a ground line on a relay board, compared to the optical module 1 according to the second embodiment, the optical module 1 according to the variant of the second embodiment can provide the optical module 1 with improved high-frequency characteristics when the semiconductor element 6 operates at high speed. Note that since electrical connections between the end portions in the direction of the first member 21 in the first electrical wiring lines 23 and the temperature controller 3 are not intended for high-frequency electrical signals, even if some of them are electrically connected through the electrical wiring lines 39 such as conductive wires, the high-frequency characteristics of the optical module 1 are not affected.

### Third Embodiment

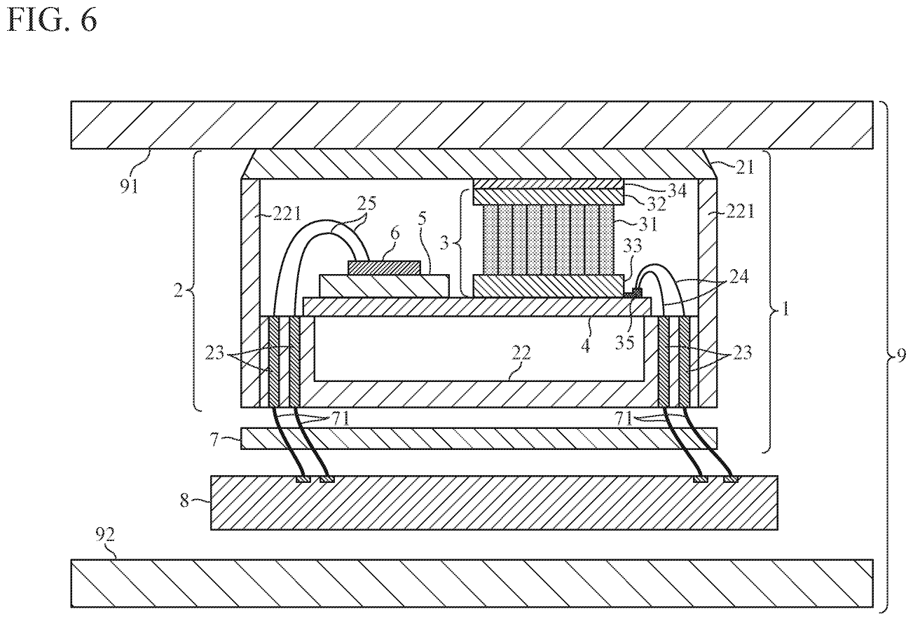

FIG. 6 is a diagram showing a configuration of a transceiver 9 in which an optical module 1 according to a third embodiment is surface-mounted on an electrical signal wiring board 8.

The configuration of the transceiver 9 in which the optical module 1 according to the third embodiment is surface-mounted on the electrical signal wiring board 8 will be described using FIG. 6.

In description of the optical module 1 according to the third embodiment, description of content overlapping the content described in the embodiments so far is omitted.

Differences between the optical module 1 according to the second embodiment and the optical module 1 according to the third embodiment are as follows:

The semiconductor element 6 in the optical module 1 according to the second embodiment is disposed in the opposite direction to the first member 21 with respect to the carrier 4. In addition, the carrier 4 in the optical module 1 according to the second embodiment includes the second electrical wiring lines 41.

On the other hand, a semiconductor element 6 in the optical module 1 according to the third embodiment is disposed in a direction of a first member 21 with respect to a carrier 4. In addition, the carrier 4 in the optical module 1 according to the third embodiment does not include second electrical wiring lines 41.

In the optical module 1 according to the second embodiment, first electrical wiring lines 23 and the semiconductor element 6 are electrically connected to each other using the electrical wiring lines 26 and the electrical wiring lines 42 through the second electrical wiring lines 41.

On the other hand, in the optical module 1 according to the third embodiment, the first electrical wiring lines 23 and the semiconductor element 6 are directly electrically connected to each other using electrical wiring lines 25.

By such a configuration, space inside a package 2 in a direction in which a temperature controller 3 is disposed with respect to the carrier 4 can be effectively used, and compared to the optical module 1 according to the second embodiment, the optical module 1 that can achieve miniaturization in a direction perpendicular to the electrical signal wiring board 8 can be provided.

A variant of the third embodiment will be described.

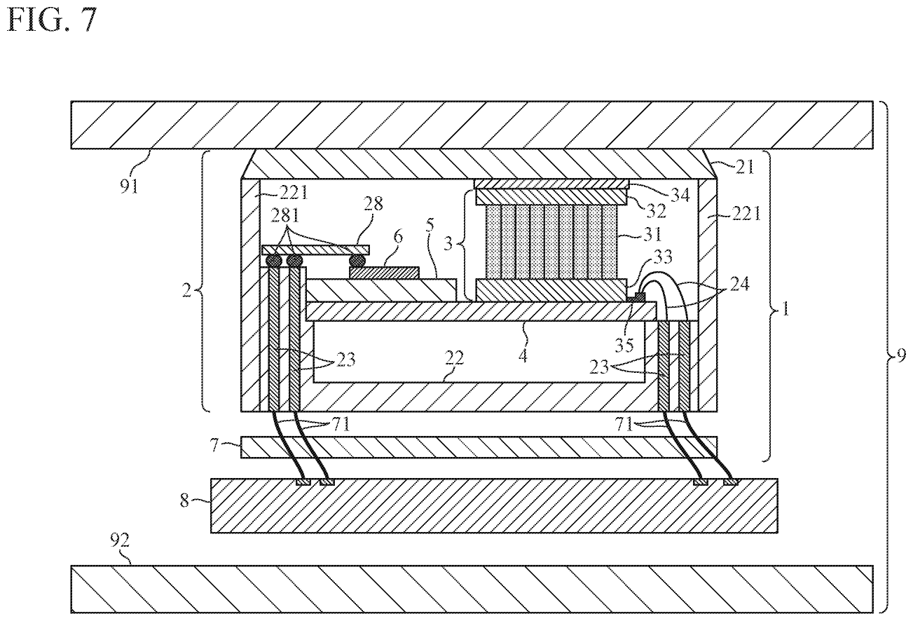

FIG. 7 is a diagram showing a configuration of a transceiver 9 in which an optical module 1 according to the variant of the third embodiment is surface-mounted on an electrical signal wiring board 8.

The configuration of the transceiver 9 in which the optical module 1 according to the variant of the third embodiment is surface-mounted on the electrical signal wiring board 8 will be described using FIG. 7.

In description of the optical module 1 according to the variant of the third embodiment, description of content overlapping the content described in the embodiments so far is omitted.

Differences between the optical module 1 according to the third embodiment and the optical module 1 according to the variant of the third embodiment are as follows.

The carrier 4 in the optical module 1 according to the third embodiment is not configured in such a manner that a surface of a second member 22 having end portions in the direction of the first member 21 in the first electrical wiring lines 23 and a surface in the direction of the first member 21 in the semiconductor element 6 are located on substantially the same plane.

On the other hand, a carrier 4 in the optical module 1 according to the variant of the third embodiment is fixed in such a manner that a surface of a second member 22 having end portions in the direction of a first member 21 in the first electrical wiring lines 23 and a surface in the direction of the first member 21 in a semiconductor element 6 are located on substantially the same plane.

FIG. 7 shows, as an example, the second member 22 processed in such a manner that a part of a side portion of the second member 22 that is in contact with the carrier 4 in FIG. 6 is cut out by an amount corresponding to the total thickness of the carrier 4, a submount 5, and the semiconductor element 6 in the opposite direction to the first member 21, in order to fix the carrier 4 in such a manner that a surface of the second member 22 having end portions in the direction of the first member 21 in the first electrical wiring lines 23 and a surface in the direction of the first member 21 in the semiconductor element 6 are located on substantially the same plane. Provided that the carrier 4 can be fixed in such a manner that a surface of the second member 22 having end portions in the direction of the first member 21 in the first electrical wiring lines 23 and a surface in the direction of the first member 21 in the semiconductor element 6 are located on substantially the same plane, the location of the carrier 4 is not limited to the structure shown in FIG. 7, and for example, the carrier 4 may be fixed in such a manner that the side portions of the second member 22 which make a pair sandwich both end sides of the carrier 4.

In addition, in the optical module 1 according to the third embodiment, the first electrical wiring lines 23 and the semiconductor element 6 are electrically connected to each other by the electrical wiring lines 25.

On the other hand, in the optical module 1 according to the variant of the third embodiment, end portions in the direction of the first member 21 in the first electrical wiring lines 23 and the semiconductor element 6 are electrically connected to each other, for example, through a relay board (hereinafter, referred to as “fourth relay board 28”) composed of a board for a flip chip and bumps (hereinafter, referred to as “third bumps 281”).

By such a configuration and an arrangement of signal lines near a ground line on a relay board, compared to the optical module 1 according to the third embodiment, the optical module 1 according to the variant of the third embodiment can provide the optical module 1 with improved high-frequency characteristics when the semiconductor element 6 operates at high speed.

### Fourth Embodiment

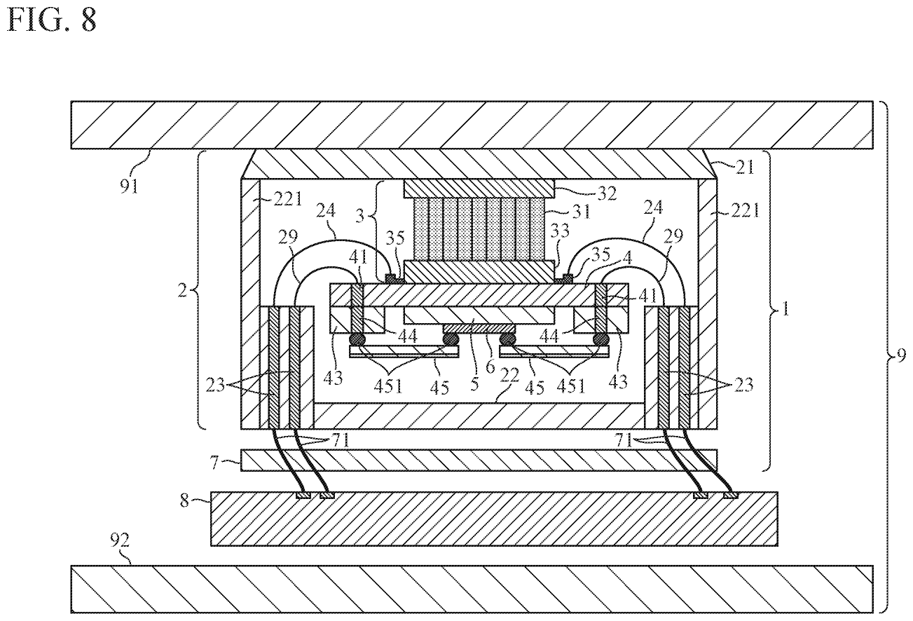

FIG. 8 is a diagram showing a configuration of a transceiver 9 in which an optical module 1 according to a fourth embodiment is surface-mounted on an electrical signal wiring board 8.

The configuration of the transceiver 9 in which the optical module 1 according to the fourth embodiment is surface-mounted on the electrical signal wiring board 8 will be described using FIG. 8.

In description of the optical module 1 according to the fourth embodiment, description of content overlapping the content described in the embodiments so far is omitted.

Differences between the optical module 1 according to the second embodiment and the optical module 1 according to the fourth embodiment are as follows:

The carrier 4 in the optical module 1 according to the second embodiment is fixed in such a manner that each of one end side of the carrier 4 and an other end side facing the one end side bridges the recessed portion of the second member 22 with a corresponding one of the side portions of the second member 22 which make a pair.

On the other hand, a carrier 4 in the optical module 1 according to the fourth embodiment is not fixed to a second member 22.

In the optical module 1 according to the fourth embodiment, first electrical wiring lines 23 and second electrical wiring lines 41 are electrically connected to each other by spring-like metals 29 composed of a flexible circuit board, etc. The carrier 4 in the optical module 1 according to the fourth embodiment is biased in a direction of a first member 21 by the spring-like metals 29 connected to end portions in the direction of the first member 21 in the second electrical wiring lines 41.

By such a configuration, compared to the optical module 1 according to the second embodiment, in the optical module 1 according to the fourth embodiment, the carrier 4 is biased in the direction of the first member 21, and thus, the carrier 4 can be suppressed from being shifted in position in the opposite direction to the first member 21, enabling to provide the optical module 1 that efficiently dissipates heat generated by a semiconductor element 6 to the first member 21.

Note that although FIG. 8 shows a configuration in which the optical module 1 according to the fourth embodiment includes first relay boards 43 and second relay boards 45, and each second electrical wiring line 41 and the semiconductor element 6 are connected to each other through a third electrical wiring line 44, a second relay board 45, and first bumps 451, the second electrical wiring line 41 and the semiconductor element 6 may be directly connected to each other by an electrical wiring line such as a conductive wire.

### Fifth Embodiment

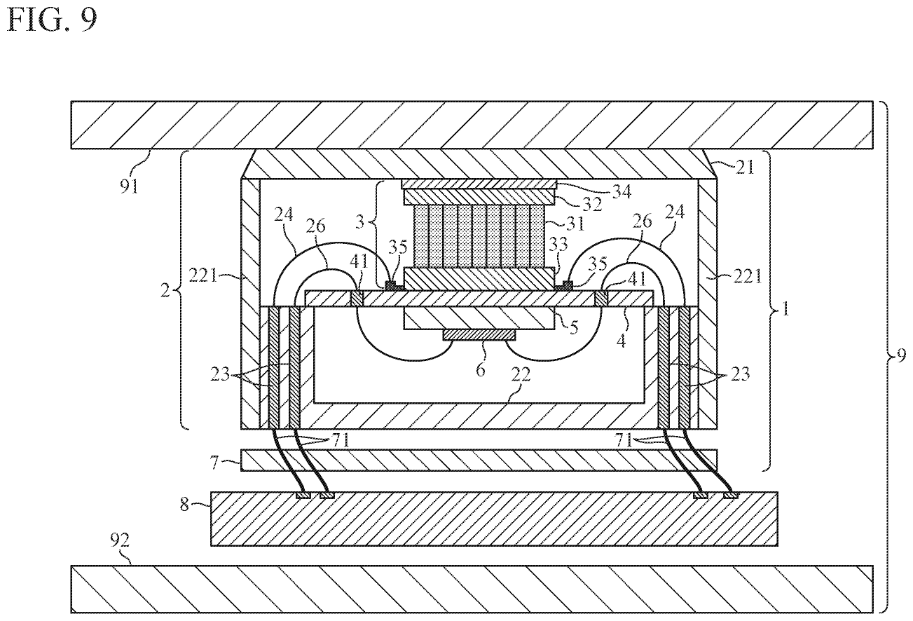

FIG. 9 is a diagram showing a configuration of a transceiver 9 in which an optical module 1 according to a fifth embodiment is surface-mounted on an electrical signal wiring board 8.

The configuration of the transceiver 9 in which the optical module 1 according to the fifth embodiment is surface-mounted on the electrical signal wiring board 8 will be described using FIG. 9.

In description of the optical module 1 according to the fifth embodiment, description of content overlapping the content described in the embodiments so far is omitted.

In the optical module 1 according to the fifth embodiment, perpendicular members 221 of a package 2 are made of a metal material.

The optical module 1 according to the fifth embodiment shown in FIG. 9 is configured in such a manner that the perpendicular members 221 of the package 2 in the optical module 1 according to the second embodiment shown in FIG. 3 are made of the same metal material as the first member 21.

By configuring the optical modules 1 according to the first to fourth embodiments described so far in such a manner that the perpendicular members 221 of the package 2 are thus made of a metal material, the optical modules 1 can be provided that can more efficiently dissipate heat generated by the semiconductor element 6 outside the optical modules 1.

In addition, by configuring the transceiver 9 using the optical module 1 in which the perpendicular members 221 of the package 2 are thus made of a metal material in such a manner that the perpendicular members 221 of the package 2 which are made of a metal material and a transceiver housing of the transceiver 9 substantially perpendicular to the transceiver housings 91 and 92 come into contact with each other, heat generated by the semiconductor element 6 can be more efficiently dissipated outside the transceiver 9.

In the embodiments described so far, the first electrical wiring lines 23 may be made of conductive vias.

In the embodiments described so far, the second electrical wiring lines 41 may be made of conductive vias.

In the embodiments described so far, the third electrical wiring lines 44 may be made of conductive vias.

Although the embodiments described so far show an example in which the optical module 1 is connected to the electrical signal wiring board 8 through the interposer 7, the optical module 1 may be directly connected to the electrical signal wiring board 8 without through the interposer 7.

Note that in the invention a free combination of the embodiments, modifications to any component of the embodiments, or omissions of any component in the embodiments are possible within the scope of the invention.

### INDUSTRIAL APPLICABILITY

Optical modules according to the invention can be applied to transceivers.

### REFERENCE SIGNS LIST

1: optical module,
2: package,
3: temperature controller,
4: carrier,
5: submount,
6: semiconductor element,
7: interposer,
8: electrical signal wiring board,
9: transceiver,
21: first member,
22: second member,
221: perpendicular member,
23: first electrical wiring line,
24: electrical wiring line,
25: electrical wiring line,
26: electrical wiring line,
27: third relay board,
28: fourth relay board,
29: spring-like metal,
31: Peltier element,
32: temperature controller's exterior member,
33: temperature controller's exterior member,
34: heat-dissipating member,
35: pole electrode,
39: electrical wiring line,
41: second electrical wiring line,
42: electrical wiring line,
43: first relay board,
44: third electrical wiring line,
45: second relay board,
71: electrical wiring line,
91: transceiver housing,
92: transceiver housing,
271: second bump,
281: third bump, and
451: first bump

What is claimed is:

1. An optical module comprising:
a package including a first member made of a metal material and a second member made of a non-conductive material, the second member facing the first member;
a temperature controller fixed in such a manner that one end surface of the temperature controller comes into contact with a surface in a direction of the second member in the first member;
a carrier made of a non-conductive material and fixed in such a manner that one end surface of the carrier comes into contact with a surface in an opposite direction to the first member in the temperature controller; and
a semiconductor element disposed in either one of a direction of the first member and the opposite direction to the first member with respect to the carrier, and fixed in such a manner that one end surface of the semiconductor element comes into contact with a surface in a direction of the first member in the carrier or a surface in the opposite direction to the first member in the carrier, or in such a manner that one end surface of the semiconductor element comes into contact with a surface in the opposite direction to the carrier in a submount made of a non-conductive material and fixed in such a manner that the submount comes in contact with a surface in a direction of the first member in the carrier or a surface in the opposite direction to the first member in the carrier, wherein
a surface in an opposite direction to the second member in the first member operates as a heat-dissipating surface, and
an electrical signal is inputted from a surface in the opposite direction to the first member in the second member,
wherein the second member has a recessed portion extending in the direction of the first member,
the second member includes a first electrical wiring line passing through the second member from a surface in the opposite direction to the first member in the second member to a surface in the direction of the first member in a part of the recessed portion of the second member, the part extending in the direction of the first member,
the carrier includes a second electrical wiring line passing through the carrier from a surface in the direction of the first member in the carrier to a surface in the opposite direction to the first member in the carrier,
the carrier is fixed so as to bridge the recessed portion of the second member,
the semiconductor element is disposed in the opposite direction to the first member with respect to the carrier,
an end portion in the direction of the first member in the first electrical wiring line and an end portion in the direction of the first member in the second electrical wiring line are electrically connected to each other, and
an end portion in the opposite direction to the first member in the second electrical wiring line and the semiconductor element are electrically connected to each other.

2. The optical module according to claim 1, wherein
the first electrical wiring line is a conductive via, and
the second electrical wiring line is a conductive via.

3. The optical module according to claim 2, wherein
the end portion in the direction of the first member in the first electrical wiring line and the end portion in the direction of the first member in the second electrical wiring line are connected to each other by a conductive wire, and
the end portion in the opposite direction to the first member in the second electrical wiring line and the semiconductor element are connected to each other by a conductive wire.

4. The optical module according to claim 2, comprising
a first relay board fixed in such a manner that one end surface of the first relay board comes into contact with a surface in the opposite direction to the first member in the carrier, a surface in the opposite direction to the first member in the first relay board being located on substantially a same plane as a surface in the opposite direction to the first member in the semiconductor element, wherein
the first relay board and the semiconductor element are electrically connected to each other on the surface in the opposite direction to the first member in the first relay board and the surface in the opposite direction to the first member in the semiconductor element through a second relay board and first bumps,
the end portion in the opposite direction to the first member in the second electrical wiring line and the semiconductor element are electrically connected to each other through the first relay board, the second relay board, and the first bumps,
the carrier is fixed in such a manner that a surface of the second member having the end portion in the direction of the first member in the first electrical wiring line and the surface in the direction of the first member in the carrier are located on substantially a same plane, and
the end portion in the direction of the first member in the first electrical wiring line and the end portion in the direction of the first member in the second electrical wiring line are electrically connected to each other through a third relay board and second bumps.

5. An optical module comprising:
a package including a first member made of a metal material and a second member made of a non-conductive material, the second member facing the first member;
a temperature controller fixed in such a manner that one end surface of the temperature controller comes into contact with a surface in a direction of the second member in the first member;
a carrier made of a non-conductive material and fixed in such a manner that one end surface of the carrier comes into contact with a surface in an opposite direction to the first member in the temperature controller; and
a semiconductor element disposed in either one of a direction of the first member and the opposite direction to the first member with respect to the carrier, and fixed in such a manner that one end surface of the semiconductor element comes into contact with a surface in a direction of the first member in the carrier or a surface in the opposite direction to the first member in the carrier, or in such a manner that one end surface of the semiconductor element comes into contact with a surface in the opposite direction to the carrier in a submount made of a non-conductive material and fixed in such a manner that the submount comes in contact with a surface in a direction of the first member in the carrier or a surface in the opposite direction to the first member in the carrier, wherein
a surface in an opposite direction to the second member in the first member operates as a heat-dissipating surface, and
an electrical signal is inputted from a surface in the opposite direction to the first member in the second member, wherein
the second member has a recessed portion extending in the direction of the first member,
the second member includes a first electrical wiring line passing through the second member from a surface in the opposite direction to the first member in the second member to a surface in the direction of the first member in a part of the recessed portion of the second member, the part extending in the direction of the first member,
the carrier is fixed so as to bridge the recessed portion of the second member,
the semiconductor element is disposed in the direction of the first member with respect to the carrier, and
an end portion in the direction of the first member in the first electrical wiring line and the semiconductor element are electrically connected to each other.

6. The optical module according to claim 5, wherein
the first electrical wiring line is a conductive via.

7. The optical module according to claim 6, wherein
the end portion in the direction of the first member in the first electrical wiring line and the semiconductor element are connected to each other by a conductive wire.

8. The optical module according to claim 6, wherein
the carrier is fixed in such a manner that a surface of the second member having the end portion in the direction of the first member in the first electrical wiring line and the surface in the direction of the first member in the semiconductor element are located on substantially a same plane, and
the end portion in the direction of the first member in the first electrical wiring line and the semiconductor element are connected to each other through a fourth relay board and third bumps.

9. An optical module comprising:
a package including a first member made of a metal material and a second member made of a non-conductive material, the second member facing the first member;
a temperature controller fixed in such a manner that one end surface of the temperature controller comes into contact with a surface in a direction of the second member in the first member;
a carrier made of a non-conductive material and fixed in such a manner that one end surface of the carrier comes into contact with a surface in an opposite direction to the first member in the temperature controller; and
a semiconductor element disposed in either one of a direction of the first member and the opposite direction to the first member with respect to the carrier, and fixed in such a manner that one end surface of the semiconductor element comes into contact with a surface in a direction of the first member in the carrier or a surface in the opposite direction to the first member in the carrier, or in such a manner that one end surface of the semiconductor element comes into contact with a surface in the opposite direction to the carrier in a submount made of a non-conductive material and fixed in such a manner that the submount comes in contact with a surface in a direction of the first member in the carrier or a surface in the opposite direction to the first member in the carrier, wherein
a surface in an opposite direction to the second member in the first member operates as a heat-dissipating surface, and
an electrical signal is inputted from a surface in the opposite direction to the first member in the second member, wherein
the second member has a recessed portion extending in the direction of the first member,
the second member includes a first electrical wiring line passing through the second member from a surface in the opposite direction to the first member in the second member to a surface in the direction of the first member in a part of the recessed portion of the second member, the part extending in the direction of the first member,
the carrier includes a second electrical wiring line passing through the carrier from a surface in the direction of the first member in the carrier to a surface in the opposite direction to the first member in the carrier,
the semiconductor element is disposed in the opposite direction to the first member with respect to the carrier,
an end portion in the direction of the first member in the first electrical wiring line and an end portion in the direction of the first member in the second electrical wiring line are electrically connected to each other by a spring-like metal in such a manner that an end portion in the direction of the first member in the second electrical wiring line is biased in the direction of the first member, and
an end portion in the opposite direction to the first member in the second electrical wiring line and the semiconductor element are electrically connected to each other.

10. The optical module according to claim 9, wherein
the first electrical wiring line is a conductive via, and
the second electrical wiring line is a conductive via.

11. The optical module according to claim 10, wherein
the end portion in the opposite direction to the first member in the second electrical wiring line and the semiconductor element are connected to each other by a conductive wire.

12. The optical module according to claim 10, comprising
a first relay board fixed in such a manner that one end surface of the first relay board comes into contact with a surface in the opposite direction to the first member in the carrier, a surface in the opposite direction to the first member in the first relay board being located on substantially a same plane as a surface in the opposite direction to the first member in the semiconductor element, wherein
the first relay board and the semiconductor element are electrically connected to each other on the surface in the opposite direction to the first member in the first relay board and the surface in the opposite direction to the first member in the semiconductor element through a second relay board and first bumps, and
the end portion in the opposite direction to the first member in the second electrical wiring line and the semiconductor element are electrically connected to each other through the first relay board, the second relay board, and the first bumps.

13. The optical module according to claim 1, wherein
a part of the package substantially perpendicular to the first member and the second member is made of a metal material.

14. The optical module according to claim 5, wherein
a part of the package substantially perpendicular to the first member and the second member is made of a metal material.

15. The optical module according to claim 9, wherein
a part of the package substantially perpendicular to the first member and the second member is made of a metal material.
